(19) United States
(12) Patent Application Publication
(10) Pub. No.: US 2026/0045962 A1
(43) Pub. Date: Feb. 12, 2026

(54) NON-LINEARITY COMPENSATION METHOD FOR APPLYING NON-LINEARITY COMPENSATION THAT IS SOURCE IMPEDANCE DEPENDENT OR MAKING SOURCE IMPEDANCE INDEPENDENT OF OFF-CHIP COMPONENTS

(71) Applicant: MEDIATEK INC., Hsinchu City (TW)

(72) Inventors: Rishabh Mittal, San Jose, CA (US); Ayman Shabra, San Jose, CA (US); Chi-Lun Lo, San Jose, CA (US); Hong Minh Nguyen, Hsinchu City (TW); Arup Mukherji, San Jose, CA (US); Stacy Ho, San Jose, CA (US); Gabriele Manganaro, San Jose, CA (US); Eunseok Lee, San Jose, CA (US); Jonathan Xiang Wu, San Jose, CA (US); Nathan Egan, San Jose, CA (US); Mahmoud Ayman Ahmed Ibrahim, San Jose, CA (US)

(73) Assignee: MEDIATEK INC., Hsinchu City (TW)

(21) Appl. No.: 19/291,592

(22) Filed: Aug. 5, 2025

Related U.S. Application Data
(60) Provisional application No. 63/681,236, filed on Aug. 9, 2024.

(51) Int. Cl. H04B 1/12; H03F 3/19

(52) U.S. Cl. CPC H04B 1/12; H03F 3/19; H03F 2200/294

(57) ABSTRACT

A non-linearity compensation method includes: performing measurement to obtain at least one measurement result for at least one first node of a receiver (RX) chain, wherein the at least one measurement result is source impedance dependent; and performing non-linearity compensation upon a processed signal generated by the RX chain, wherein the non-linearity compensation is based at least partly on the at least one measurement result.

### CROSS REFERENCE TO RELATED APPLICATIONS

This application claims the benefit of U.S. Provisional Application No. 63/681,236, filed on Aug. 9, 2024. The content of the application is incorporated herein by reference.

### BACKGROUND

The present invention relates to a wireless receiver design, and more particularly, to a non-linearity compensation method for applying non-linearity compensation that is source impedance dependent or making a source impedance independent of off-chip components.

For wideband receivers (e.g., 5G/sub-6G base station applications), the system distortion can change due to different impedance conditions on customer's end. The base station applications may require a spurious free dynamic range (SFDR) better than 70 dB. The SFDR is typically limited by the second-order harmonic distortion (HD2) and the third-order harmonic distortion (HD3). To achieve such high SFDR performance, a non-linearity cancellation (NLC) technique may be implemented in a wideband receiver. However, a source-dependent distortion makes the NLC outcome unpredictable, often resulting in insufficient HD3 cancellation (or in some cases, the digital NLC can worsen the system's baseline distortion). For example, for different lengths of a transmission line routed on a printed circuit board (PCB), different source impedances can be seen by an on-chip RX analog front-end (AFE). As a result, a distortion model constructed in production testing may not work well in the customer's system due to distortion variation (which includes magnitude and phase variations) that is source impedance dependent. Thus, there is a need for an innovative non-linearity compensation (also called non-linearity cancellation or non-linearity correction) technique which is capable of mitigating the source-dependent non-linearity distortion (particularly, source-dependent HD3) in a wideband receiver.

### SUMMARY

One of the objectives of the claimed invention is to provide a non-linearity compensation method for applying non-linearity compensation that is source impedance dependent or making a source impedance independent of off-chip components.

According to a first aspect of the present invention, an exemplary non-linearity compensation method is disclosed. The exemplary non-linearity compensation method includes: performing measurement to obtain at least one measurement result for at least one first node of a receiver (RX) chain, wherein at least one measurement result is source impedance dependent; and performing non-linearity compensation upon a processed signal generated by the RX chain, wherein the non-linearity compensation is based at least partly on one measurement result.

According to a second aspect of the present invention, an exemplary distortion transfer function (DTF) estimation method is disclosed. The exemplary DTF estimation method includes: providing a stimulus injected to a first node of a receiver (RX) chain; performing measurement at a second node of the RX chain to generate a measurement result; and estimating a DTF between the first node and the second node according to the stimulus and the measurement result.

According to a third aspect of the present invention, an exemplary non-linearity compensation method is disclosed. The exemplary non-linearity compensation method includes: receiving, by a chip, an input signal from a source, wherein the chip comprises on-chip components of a receiver (RX) chain for processing the input signal, the source comprises off-chip components of the RX chain for providing the input signal, and at least one of the off-chip components is an off-chip reflectionless component; and performing non-linearity compensation upon a processed signal generated by the RX chain.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a wideband receiver that employs the proposed non-linearity compensation method according to an embodiment of the present invention.

FIG. 2 is a diagram illustrating a distortion generation hypothesis according to an embodiment of the present invention.

FIG. 3 is a diagram illustrating an impedance-based approach for in-situ parameter extraction according to an embodiment of the present invention.

FIG. 4 is a diagram illustrating HD3 modeling that only includes pre-amplifier's HD3 dependence on the source impedance according to an embodiment of the present invention.

FIG. 5 is a diagram illustrating an arrangement of finding NLC parameters during a chip production procedure according to an embodiment of the present invention.

FIG. 6 is a diagram illustrating one implementation of the NLC circuit according to an embodiment of the present invention.

FIG. 7 is a diagram illustrating a DTF-based approach for in-situ parameter extraction according to an embodiment of the present invention.

FIG. 8 is a diagram illustrating another implementation of the NLC circuit according to an embodiment of the present invention.

FIG. 9 is a diagram illustrating another implementation of the NLC circuit according to an embodiment of the present invention.

FIG. 10 is a diagram illustrating a wideband receiver that employs another proposed non-linearity compensation method according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical or magnetic connection. Accordingly, if one device is coupled to another device, that connection may be through a direct electrical or magnetic connection, or through an indirect electrical or magnetic connection via other devices and connections.

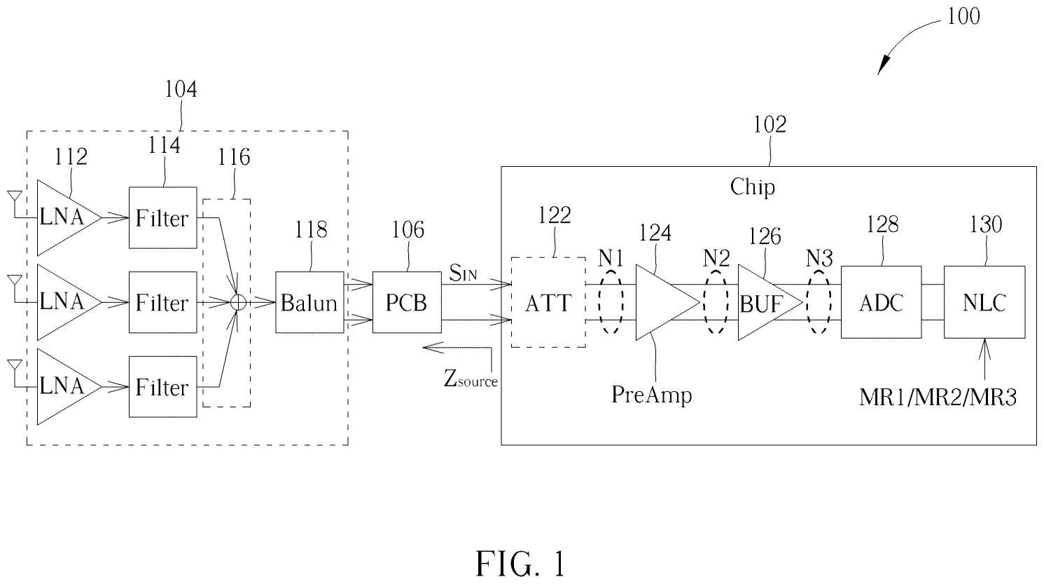

FIG. 1 is a diagram illustrating a wideband receiver that employs the proposed non-linearity compensation method according to an embodiment of the present invention. The wideband receiver 100 includes a chip 102 and an off-chip source 104. The chip 102 is mounted on a PCB 106. The chip 102 is coupled to the off-chip source 104 via transmission lines routed on the PCB 106, and receives an input signal S_{IN} provided from the off-chip source 104. Specifically, the chip 102 includes on-chip components of an RX chain for processing the input signal S_{IN}, and the off-chip source 104 includes off-chip components of the RX chain for providing the input signal S_{IN}. The off-chip source 104 of the wideband receiver 100 includes a plurality of channels, each having a low-noise amplifier (LNA) 112 and a filter 114. For example, the filter 114 may be a band-pass filter (BPF). The off-chip source 104 further includes a radio-frequency (RF) combiner 116 and a balun 118. Since the present invention is not focused on the hardware design of the off-chip source 104, further description of the off-chip source 104 is omitted here for brevity.

The chip 102 may include an attenuator circuit (labeled by “ATT”) 122, a pre-amplifier circuit (labeled by “PreAmp”) 124, a buffer circuit (labeled by “BUF”) 126, an analog-to-digital converter (ADC) circuit (labeled by “ADC”) 128, and a non-linearity cancellation (NLC) circuit (labeled by “NLC”) 130. For example, the attenuator circuit 122 may be a digital step attenuator (DSA) for applying a variable gain to a chip input (i.e., input signal SIN). When the chip 102 is used in different customers' receiver applications, source impedances Z_{source} Viewed from the chip 102 may be different, causing source-dependent distortion (e.g., source-dependent HD3). To address the source-dependent distortion issue, the present invention proposes a non-linearity compensation method that is capable of improving the HD3 cancellation performance of the NLC circuit 130. For example, the proposed non-linearity compensation method performs measurement to obtain at least one measurement result MR1/MR2/MR3 for at least one node N1/N2/N3 of the RX chain, and performs non-linearity compensation upon a processed signal (e.g., an ADC output) generated by the RX chain, where the at least one measurement result MR1/MR2/MR3 is source impedance dependent, and the non-linearity compensation performed at the NLC circuit 130 is based at least partly on the at least one measurement result MR1/MR2/MR3. Digital mitigation of source-dependent distortion variation is achieved by the proposed non-linearity compensation method. The number of measurement results used by non-linearity compensation depends on actual design considerations. For example, HD3 estimation accuracy can be improved through using more measurement results obtained for different on-chip nodes of the RX chain. Further details of the proposed non-linearity compensation method are described as below with reference to the accompanying drawings.

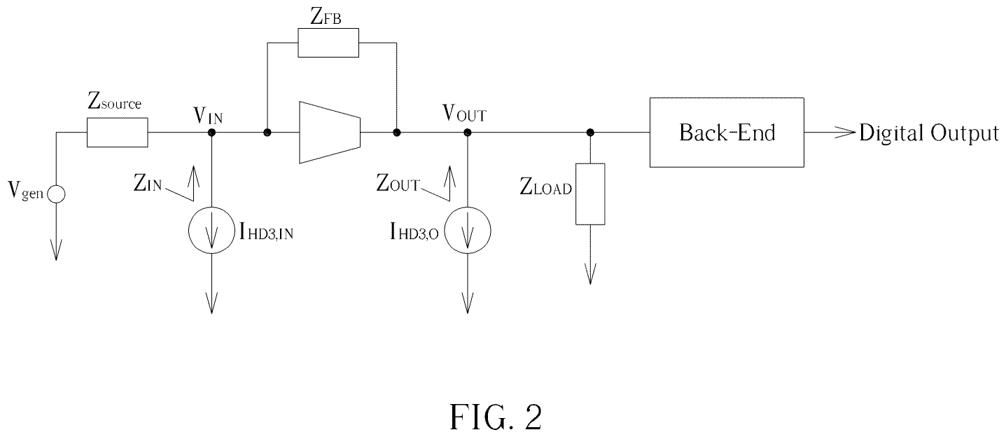

In one embodiment of the present invention, the proposed non-linearity compensation method may adopt an impedance-based approach to obtain at least one measurement result MR1/MR2/MR3 involved in the follow-up non-linearity compensation at the NLC circuit 130. In another embodiment of the present invention, the proposed non-linearity compensation method may adopt a distortion transfer function (DTF) based approach to obtain at least one measurement result MR1/MR2/MR3 involved in the follow-up non-linearity compensation at the NLC circuit 130. FIG. 2 is a diagram illustrating a distortion generation hypothesis according to an embodiment of the present invention. The system is weakly nonlinear. The distortion may be modeled by current generators. As shown in FIG. 2, one current generator provides a current I_{HD3,IN}, and another current generator provides a current I_{HD3,0}. The current I_{HD3,IN} flowing through an impedance Z_{IN} generates a voltage V_{IN}. The current I_{HD3,O} flowing through an impedance Zₒᵤₜ generates a voltage Vₒᵤₜ. Each of the impedances Z_{IN} and Zₒᵤₜ is a function of the source impedance Z_{source}. In other words, the impedances Z_{IN} and Zₒᵤₜ are source impedance dependent. Distortion will see a linear DTF to the output. If I_{HD3,IN} and I_{HD3,0} are source impedance dependent, a distortion transfer function DTF_{Iin} of I_{HD3,IN} and a distortion transfer function DTF_{Iout} of I_{HD3,0} can be used to compensate for the source-dependent distortion.

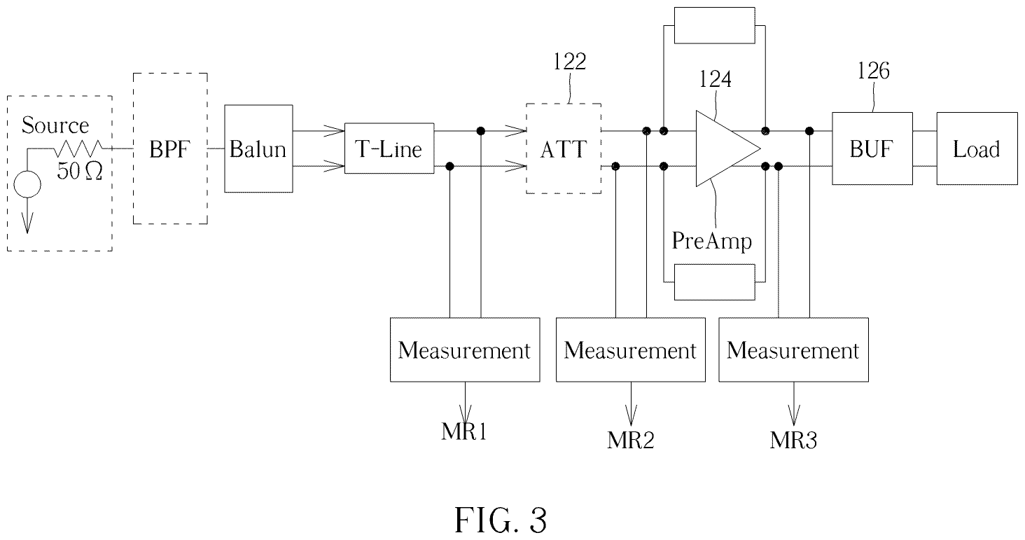

FIG. 3 is a diagram illustrating an impedance-based approach for in-situ parameter extraction according to an embodiment of the present invention. An impedance measurement device is necessary in this approach. For example, the impedance measurement device may be a vector network analyzer (VNA) or a low-to-medium resolution current DAC. For another example, a DAC may be used to inject a small current, and then a voltage is read at an ADC output. However, these are for illustrative purposes only, and are not meant to be limitations of the present invention. As shown in FIG. 1, measurement is performed to obtain at least one measurement result MR1/MR2/MR3 for at least one node N1/N2/N3 of the RX chain. In accordance with the impedance-based approach for in-situ parameter extraction, impedance measurements may be done at an input of the attenuator circuit 122 (i.e., on-chip node N1), an input of the pre-amplifier circuit 124 (i.e., on-chip node N2), and an output of the pre-amplifier circuit 124 (i.e., on-chip node N3). It should be noted that impedance measurements at an input of the pre-amplifier circuit 124 (i.e., on-chip node N2) and an output of the pre-amplifier circuit 124 (i.e., on-chip node N3) may be sufficient to fully capture pre-amplifier's HD3 dependence on the source impedance. To capture the impact of attenuator's HD3 dependence on the source impedance, measurements at an input of the attenuator circuit 122 (i.e., on-chip node N1) and an output of the attenuator circuit 122 (i.e., on-chip node N2) will be necessary.

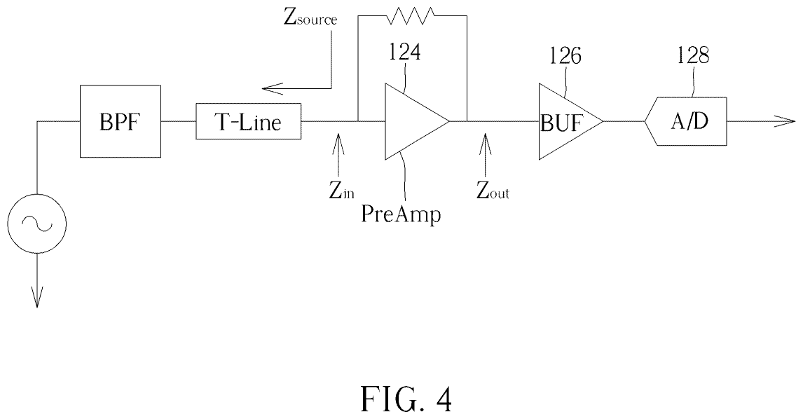

For brevity and simplicity, HD3 modeling that only includes pre-amplifier's HD3 dependence on the source impedance is illustrated in FIG. 4. The source-dependent distortion (HD3=f (Z_{source}) may be represented by f(Zᵢₙ), f(Zₒᵤₜ), or a combination of both, where Zᵢₙ is a function of Z_{source} and can be obtained by impedance measurement at the input of the pre-amplifier circuit 124, and Zₒᵤₜ is a function of Z_{source} and can be obtained by impedance measurement at the output of the pre-amplifier circuit 124. Consider a case where the source-dependent distortion is a function of Zₒᵤₜ, computation of an HD3 estimate HD_{3,est} may be expressed using the following formula.

$$H {D}_{3 , e s t} = f ( {Z}_{o u t} ) = {H}_{3} \cdot \vert {Z}_{o u t} \vert \cdot {\vert {A}_{{f}_{i n}} \vert}^{3} \cdot {e}^{j ( 3 \cdot {ϕ}_{{f}_{in}} + {ϕ}_{{z}_{out}} + {ϕ}_{3} )} \qquad ( 1 )$$

In above formula (1), H₃·|Zₒᵤₜ|·|A_{f}_{ᵢₙ}|³ is a magnitude term, and is a phase term, where H₃ represents a scaling constant, ϕ₃ represents a phase-shift constant (H₃ and ϕ₃ combined can be seen as a complex scaling factor), Zₒᵤₜ represents magnitude of the impedance measured at the pre-amplifier output, ϕ_{zout} represents phase of the impedance measured at the pre-amplifier output, A_{f}_{ᵢₙ} represents magnitude of the fundamental tone as measured from RX output Fast Fourier Transform (FFT), and ϕ_{f}_{ᵢₙ} represents phase of the fundamental tone as measured from RX output FFT. The HD3 estimate obtained from the formula (1) is source impedance dependent, and can be used by non-linearity compensation performed at the NLC circuit 130 to mitigate the source-dependent third-order non-linearity in the wideband receiver 100.

The source-dependent HD3 estimate based on only Zₒᵤₜ of the pre-amplifier circuit 124 (i.e., the HD3 estimate that is obtained from the formula (1)) may not capture both the magnitude and phase variations accurately. In some embodiments of the present invention, the source-dependent HD3 may be a function of Zₒᵤₜ and Zᵢₙ, and computation of an HD3 estimate HD3,est may be expressed using the following modified formula.

$$H {D}_{3 , e s t} = f ( {Z}_{out} , {Z}_{i n} ) = \{ {H}_{3 , zout} {e}^{j {ϕ}_{3 , zout}} \cdot \vert {Z}_{out} \vert {e}^{j {ϕ}_{zout}} + {H}_{3 , z i n} {e}^{j {ϕ}_{3 , zin}} \cdot \vert {Z}_{i n} \vert {e}^{j {ϕ}_{zin}} \} \cdot {\vert {A}_{{f}_{i n}} \vert}^{3} {e}^{j 3 {ϕ}_{fin}} \qquad ( 2 )$$

The function f(·) may be constructed empirically, with the goal to emulate the circuit's HD3 magnitude and phase behavior across the 1 GHz-8 GHz frequency bands as well as for arbitrary choice of transmission line lengths. In above formula (2), H_{3,zout} represents magnitude scaling constant for Zₒᵤₜ, P_{3,zout} represents phase-shift constant (H_{3,zout} and ϕ_{3,zout} combined can be seen as a complex scaling factor), H_{3,zin} represents magnitude scaling constant for Zᵢₙ, ϕ_{3,zin} represents phase-shift constant (H_{3,zin} and ϕ_{3,zin} combined can be seen as a complex scaling factor), Zₒᵤₜ and Zᵢₙ represent magnitude of the impedance measured at the pre-amplifier output and pre-amplifier input, respectively, ϕ_{zout} and ϕ_{zin} represent phase of the impedance measured at the pre-amplifier output and pre-amplifier input, respectively, A_{f}_{ᵢₙ} represents magnitude of the fundamental tone as measured from RX output FFT, and ϕ_{f}_{ᵢₙ} represents phase of the fundamental tone as measured from RX output FFT.

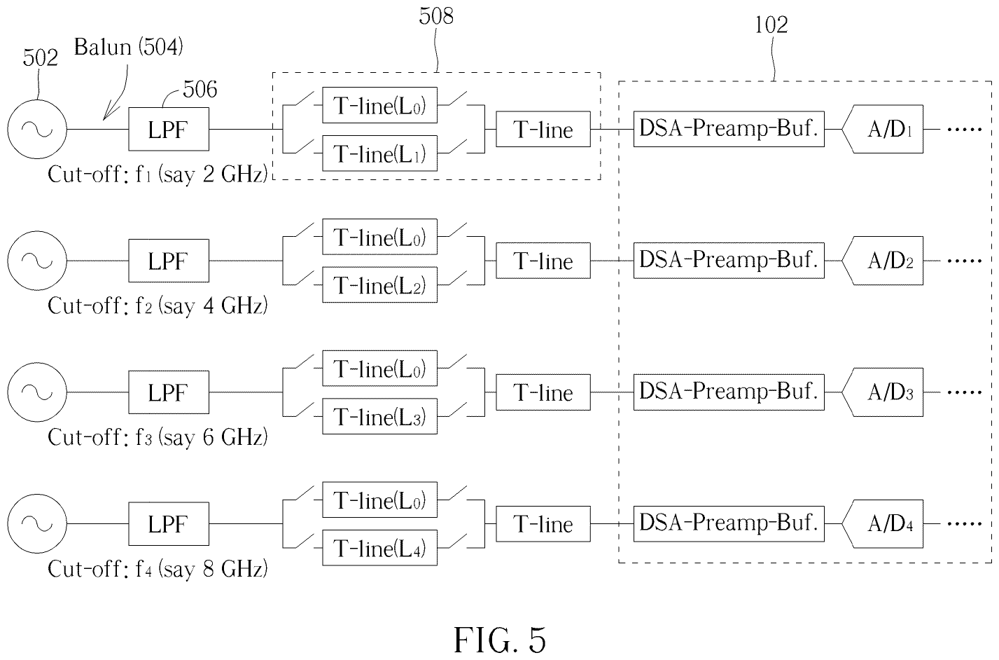

Regarding the formula (1), one non-linearity compensation parameter set consisting of two NLC parameters (H3, ϕ₃) is needed. Regarding the formula (2), two non-linearity compensation parameter sets consisting of four NLC parameters (H_{3,zout}, ϕ_{3,zout}) and (H_{3,zin}, ϕ_{3,zin}) are needed. In some embodiments of the present invention, these NLC parameters may be obtained during production characterization. FIG. 5 is a diagram illustrating an arrangement of finding NLC parameters during a chip production procedure according to an embodiment of the present invention. The chip 102 may support 4 RX channels, each having a signal generator 502, a balun 504, a low-pass filter (LPF) 506, and a controllable transmission line 508. The LPF 506 may be implemented using a simple first-order shunt capacitor. The balun 504 between the signal generator 502 and the LPF 506 may need to be wideband (at least up to 8 GHZ). The controllable transmission line 508 is used to provide a variable transmission line (T-line) length that is necessary to estimate the NLC parameters used in the proposed non-linearity cancellation. For example, the variable T-line length may be achieved by a tunable phase shifter. In this embodiment, different T-line lengths L₀, L₁, L₂, L₃, L₄ are chosen, such that reasonable transmission line length points and HD3 data are obtained during production characterization.

Specifically, during production characterization, the proposed non-linearity compensation method measures impedance at one or more on-chip nodes (e.g., attenuator input, pre-amplifier input, and/or pre-amplifier output) under different frequency bands (e.g., 2 GHz, 4 GHZ, 6 GHZ, and 8 GHz) and different transmission line lengths (e.g., L₀, L₁, L₂, L₃, and L₄), to generate a plurality of non-linearity compensation parameter sets for the different frequency bands (e.g., (H3, ϕ₃) for 2 GHz band, (H₃, ϕ₃) for 4 GHz band, (H₃, ϕ₃) for 6 GHZ band, and (H₃, ϕ₃) for 8 GHz band), respectively. The (H₃, ϕ₃) parameters are not very sensitive to the center frequency at which the parameters are calculated. However, for large frequency changes, e.g., 2+ GHz, the parameters should be re-evaluated because the intrinsic distortion of the circuit changes and the (H₃, ϕ₃) parameters must reflect this change. Furthermore, the number of frequency bands required to characterize the entire wideband receiver will depend on the final SFDR specifications and the system implementation details, but generally, approximately 4-6 bands may be used for creating the (H3, ϕ₃) vs. frequency look-up table (LUT).

In accordance with the production characterization approach, the impedance is measured using multiple transmission lines with different lengths. This identifies filtering components for use in the compensator that separately account for the distortion components that depend on the source and those that don't. The NLC circuit 130 is used to calculate an HD3 estimate and subtract the HD3 estimate from a processed signal (e.g., an ADC output) of the RX chain for non-linearity compensation. In a case where the impedance-based approach is adopted for in-situ parameter extraction, the digital non-linearity compensation performed at the NLC circuit 130 is based at least partly on impedance measurement result(s) and a non-linearity compensation parameter set, where the non-linearity compensation parameter set is selected from the non-linearity compensation parameter sets that are obtained during production characterization and recorded in the LUT.

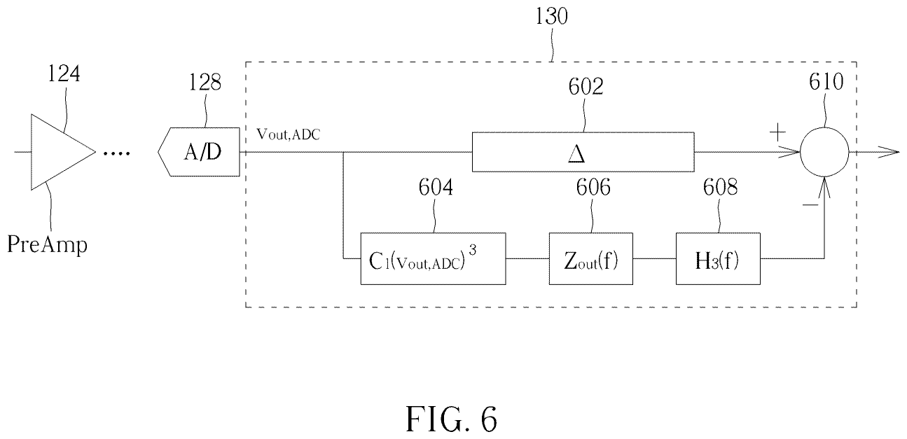

FIG. 6 is a diagram illustrating one implementation of the NLC circuit 130 according to an embodiment of the present invention. In this embodiment, the NLC circuit 130 may calculate an HD3 estimate according to the aforementioned formula (1). As shown in FIG. 6, the NLC circuit 130 includes a delay circuit 602 and a compensator that has a plurality of processing circuits 604, 606, 608 and a combining circuit 610. The compensator is used to calculate an HD3 estimate HD_{3,est} and subtract the HD3 estimate HD_{3,est} from the ADC output V_{out,ADC} for mitigating the source-dependent third-order non-linearity in the wideband receiver. To that end, the processing circuit 604 calculates the cube of an ADC output V_{out,ADC}. The processing circuit 606 multiplies an output of the processing circuit 604 by a value derived from an impedance measurement result (which is, for instance, measured at an output of the pre-amplifier circuit 124). The processing circuit 608 is a digital filter which essentially encodes the LUT of (H3, ϕ₃) used in HD3 cancelation. The HD3 estimate is output from the processing circuit 608 to the combining circuit 610. The combining circuit 610 acts as a subtractor for subtracting the HD3 estimate from a delayed version of the ADC output V_{out,ADC} for HD3 cancelation. The implementation shown in FIG. 6 is for illustrative purposes only, and is not meant to be a limitation of the present invention. In practice, any means capable of performing non-linearity compensation based at least partly on impedance measurement result(s) that are source impedance dependent falls within the scope of the present invention. For example, a compensator of the NLC circuit 130 may calculate an HD3 estimate according to the aforementioned formula (2).

It should be noted that the attenuator circuit (e.g., DSA) 122 may have impact on the HD3 variation. In other words, the HD3 mechanism is DSA code dependent. The (H3, ϕ₃) parameters capture the circuit's intrinsic distortion, and will therefore also depend on the DSA code. A LUT must be constructed to adjust the (H3, ϕ₃) parameters based on the DSA code. Combining this LUT with the frequency LUT will result in a master LUT in which the relation of (H3, ϕ₃) parameters with the frequency and DSA code can be encoded. In a real implementation, the details of the LUT will depend on system-level decisions, such as trade-offs between the customer spec and the system's complexity.

In some embodiments of the present invention, the non-linearity compensation method may further use a temperature sensor for sensing temperature of on-chip components of the RX chain to generate a temperature sensing output. The non-linearity compensation performed at the NLC circuit 130 may be adjusted based on the temperature sensing output. For example, the filtering components' weights of the compensator used in the NLC circuit 130 shown in FIG. 6 are adjusted based on temperature using a 1st order or higher order temperature coefficient.

In above embodiments, the non-linearity compensation method adopts an impedance-based approach to obtain one or more measurement results MR1, MR2, MR3 involved in the follow-up non-linearity compensation at the NLC circuit 130. In some embodiments of the present invention, the non-linearity compensation method may adopt a DTF-based approach to obtain one or more measurement results MR1, MR2, MR3 involved in the follow-up non-linearity compensation at the NLC circuit 130.

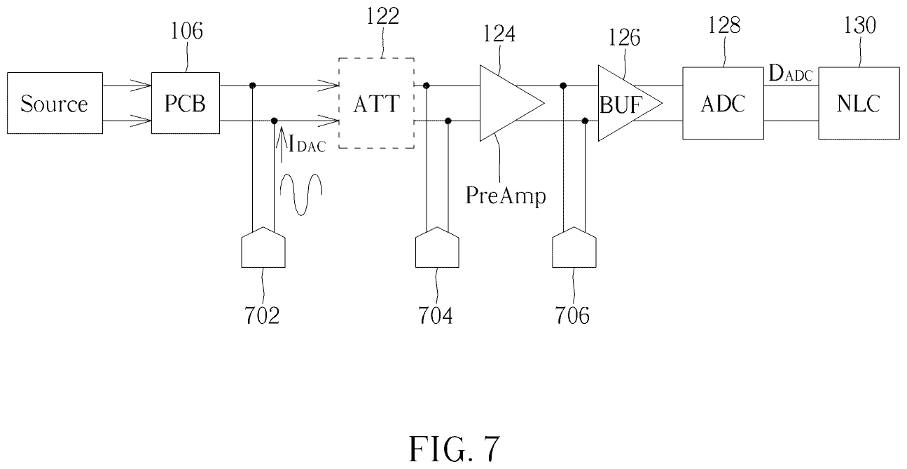

FIG. 7 is a diagram illustrating a DTF-based approach for in-situ parameter extraction according to an embodiment of the present invention. A DTF between a first node of the RX chain and a second node of the RX chain is measured. The first node may be an input of the attenuator circuit 122, an input of the pre-amplifier circuit 124 (which is also an output of the attenuator circuit 122), or an output of the pre-amplifier circuit 124. The second node may be an output of the ADC circuit 128 or after digital processing of the output of the ADC circuit 128. As shown in FIG. 7, a stimulus generator circuit 702 is used to provide a stimulus injected to the input of the attenuator circuit 122, a stimulus generator circuit 704 is used to provide a stimulus injected to the input of the pre-amplifier circuit 124 (which is also the output of the attenuator circuit 122), and a stimulus generator circuit 706 is used to provide a stimulus injected to the output of the pre-amplifier circuit 124. For example, the stimulus generator circuit 702/704/706 may be implemented using a DAC circuit, a phase-locked loop (PLL) circuit, or an oscillator circuit. For another example, the stimulus provided from the stimulus generator circuit 702/704/706 may be a 1-bit digital waveform.

Consider a case where the stimulus generator circuit 702/704/706 is implemented using a DAC circuit, and the digital ADC output DADC is measured for DTF estimation. The DTF is estimated at each relevant frequency by applying a DAC current I_{DAC} to a first node (e.g., attenuator input, pre-amplifier input, or pre-amplifier output) and measuring DADE at the second node (e.g., ADC output), where the DAC current I_{DAC} may be differential or common-mode. The common-mode excitation is needed to compensate for even-order HD terms. After DADE is measured under the stimulus set by I_{DAC}, the DTF may be determined by

$$\frac{{D}_{ADC}}{{I}_{DAC}} .$$

It should be noted that full knowledge of I_{DAC} is not needed as long as it remains consistent from production characterization to the actual usage case. The DTF-based approach may be used to obtain DTF₁ (which is a DTF between an attenuator input and an ADC output), DTF₂ (which is a DTF between a pre-amplifier input and an ADC output), and/or DTF₃ (which is a DTF between a pre-amplifier output and an ADC output) that are needed by the follow-up non-linearity compensation at the NLC circuit 130.

In some embodiments of the present invention, the DAC circuit used for generating the stimulus I_{DAC} may be a current DAC, a resistive DAC, or a capacitive DAC. In some embodiments of the present invention, the DAC circuit used for generating the stimulus I_{DAC} may employ a noise shaping technique to reduce the required DAC resolution. In some embodiments of the present invention, the DAC circuit used for generating the stimulus I_{DAC} may operate in the 1^{st}-order Nyquist zone or a higher-order Nyquist zone. In some embodiments of the present invention, the DAC circuit used for generating the stimulus I_{DAC} may be clocked at a rate higher than a sampling rate of the ADC circuit 128 to allow for measurement of high-order distortion transform functions.

Considering a case where all of DTF₁, DTF₂, and DTF₃ are used by the follow-up non-linearity compensation at the NLC circuit 130, the source-dependent distortion is a function of DTF₁, DTF₂, and DTF₃, and computation of an HD3 estimate HD_{3,est} may be expressed using the following formula.

$$H {D}_{3 , e s t} = {H}_{3 , 1} \cdot \vert {DTF}_{1} \vert \cdot {\vert {A}_{{f}_{i n}} \vert}^{3} \cdot {e}^{( 3 \cdot {ϕ}_{{f}_{in}} + {ϕ}_{{DTF}_{1}} + {ϕ}_{3 , 1} )} + {H}_{3 , 2} \cdot \vert {DTF}_{2} \vert \cdot {\vert {A}_{{f}_{i n}} \vert}^{3} \cdot {e}^{( 3 \cdot {ϕ}_{{f}_{in}} + {ϕ}_{{DTF}_{2}} + {ϕ}_{3 , 2} )} + {H}_{3 , 3} \cdot \vert {DTF}_{3} \vert \cdot {\vert {A}_{{f}_{i n}} \vert}^{3} \cdot {e}^{( 3 \cdot {ϕ}_{{f}_{in}} + {ϕ}_{{DTF}_{3}} + {ϕ}_{3 , 3} )} \qquad ( 3 )$$

In above formula (3), H_{3,1} represents a scaling constant that accounts for the distortion component independent of DTF₁, H_{3,2} represents a scaling constant that accounts for the distortion component independent of DTF₂, H_{3,3} represents a scaling constant that accounts for the distortion component independent of DTF₃, ϕ_{3,1}, ϕ_{3,2}, and ϕ_{3,3} represent phase-shift constants, DTF represents magnitude of a DTF estimated between an attenuator input and an ADC output, DTF₂ represents magnitude of a DTF estimated between a pre-amplifier input and an ADC output, DTF₃ represents magnitude of a DTF estimated between a pre-amplifier output and an ADC output, ϕ_{DTF}_{₁} represents phase of a DTF estimated between an attenuator input and an ADC output, ϕ_{DTF}_{₂} represents phase of a DTF estimated between a pre-amplifier input and an ADC output, ϕ_{DTF}_{₃} represents phase of a DTF estimated between a pre-amplifier output and an ADC output, A_{f}_{ᵢₙ} represents magnitude of the fundamental tone as measured from RX output FFT, and ϕ_{f}_{ᵢₙ} represents phase of the fundamental tone as measured from RX output FFT. The HD3 estimate obtained from the formula (3) can be used by digital non-linearity compensation performed at the NLC circuit 130 for mitigating source-dependent third-order non-linearity in the wideband receiver 100.

Regarding the formula (3), one non-linearity compensation parameter set consisting of NLC parameters (H_{3,1}, ϕ_{3,1}), (H_{3,2}, ϕ_{3,2}), (H_{3,3}, ϕ_{3,3}) is needed. In some embodiments of the present invention, these NLC: parameters may be obtained during production characterization. The production characterization approach for finding NLC parameters needed by formula (3) is similar to that for NLC parameters needed by formula (1) or (2). Specifically, during production characterization, the proposed non-linearity compensation measures DTF at one or more on-chip nodes (e.g., attenuator input, pre-amplifier input, and/or pre-amplifier output) under different frequency bands (e.g., 2 GHZ, 4 GHZ, 6 GHZ, and 8 GHZ) and different transmission line lengths (e.g., L₀, L₁, L₂, L₃, and L₄), to generate a plurality of non-linearity compensation parameter sets for the different frequency bands (e.g., [(H_{3,1}, ϕ_{3,1}), (H_{3,2}, ϕ_{3,2}), (H_{3,3}, ϕ_{3,3})] for 2 GHZ band, [(H_{3,1}, ϕ_{3,1}), (H_{3,2}, ϕ_{3,2}), (H_{3,3}, ϕ_{3,3})] for 4 GHZ band, [(H_{3,1}, ϕ_{3,1}), (H_{3,2}, ϕ_{3,2}), (H_{3,3}, ϕ_{3,3})] for 6 GHZ band, and [(H_{3,1}, ϕ_{3,1}), (H_{3,2}, ϕ_{3,2}), (H_{3,3}, ϕ_{3,3})] for 8 GHZ band), respectively.

In accordance with the production characterization approach, the distortion transfer function is measured using multiple transmission lines with different lengths. This identifies filtering components for use in the compensator that separately account for the distortion components that depend on the source and those that don't. The NLC circuit 130 is used to calculate an HD3 estimate and subtract the HD3 estimate from a processed signal (e.g., an ADC output) of the RX chain for non-linearity compensation. In a case where the DTF-based approach is adopted for in-situ parameter extraction, the digital non-linearity compensation performed at the NLC circuit 130 is based at least partly on DTF measurement result(s) and a non-linearity compensation parameter set, where the non-linearity compensation parameter set is selected from the non-linearity compensation parameter sets that are obtained during production characterization and recorded in the LUT.

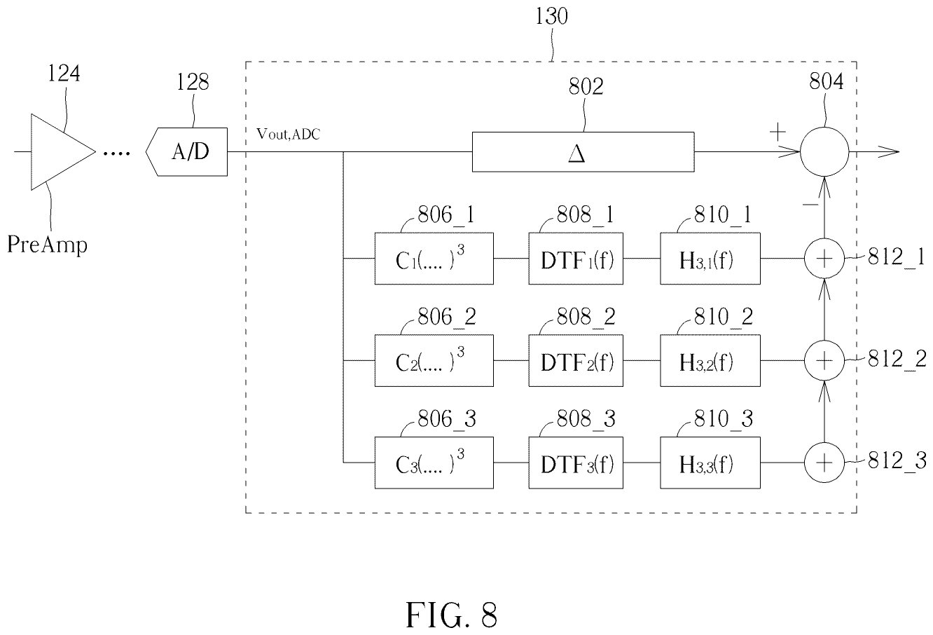

FIG. 8 is a diagram illustrating another implementation of the NLC circuit 130 according to an embodiment of the present invention. In this embodiment, the NLC circuit 130 may calculate an HD3 estimate according to the aforementioned formula (3). As shown in FIG. 8, the NLC circuit 130 includes a delay circuit 802, a combining circuit (which acts as a subtractor) 804, a plurality of processing circuits 806_1-806_3, 808_1-808_3, 810_1-810_3, and a plurality of combining circuits (which act as adders) 812_1-812_3. Each of the processing circuits 806_1-806_3 calculates the cube of an ADC output V_{out,ADC}. The processing circuit 808_1 multiplies an output of the processing circuit 806_1 by a value derived from the DTF measurement result DTF₁. The processing circuit 808_2 multiplies an output of the processing circuit 806_2 by a value derived from a DTF measurement result DTF₂. The processing circuit 808_3 multiplies an output of the processing circuit 806_3 by a value derived from a DTF measurement result DTF₃. The processing circuits 810_1-810_3 are digital filters, each operating on a NLC parameter set selected from an LUT that is created by production characterization. An HD3 estimate is generated from summing up outputs of the processing circuits 810_1-810_3. The combining circuit 804 acts as a subtractor for subtracting the HD3 estimate from a delayed version of the ADC output V_{out,ADC} for HD3 cancelation. The implementation shown in FIG. 8 is for illustrative purposes only, and is not meant to be a limitation of the present invention. In practice, any means capable of performing non-linearity compensation based at least partly on DFT measurement result(s) that are source impedance dependent falls within the scope of the present invention.

In some embodiments of the present invention, the HD3 estimate may be modified to add a DTF-independent term. For example, the DTF-independent term may capture impedance-independent effects for certain front-end designs. For another example, backend distortion can in-part be also captured by the DTF-independent term. Computation of an HD3 estimate HD_{3,est} may be expressed using the following formula.

$$H {D}_{3 , e s t} = {H}_{3 , 1} \cdot \vert {DTF}_{1} \vert \cdot {\vert {A}_{{f}_{i n}} \vert}^{3} \cdot {e}^{( 3 \cdot {ϕ}_{{f}_{in}} + {ϕ}_{{DTF}_{1}} + {ϕ}_{3 , 1} )} + {H}_{3 , 2} \cdot \vert {DTF}_{2} \vert \cdot {\vert {A}_{{f}_{i n}} \vert}^{3} \cdot {e}^{( 3 \cdot {ϕ}_{{f}_{in}} + {ϕ}_{{DTF}_{2}} + {ϕ}_{3 , 2} )} + {H}_{3 , 3} \cdot \vert {DTF}_{3} \vert \cdot {\vert {A}_{{f}_{i n}} \vert}^{3} \cdot {e}^{( 3 \cdot {ϕ}_{{f}_{in}} + {ϕ}_{{DTF}_{3}} + {ϕ}_{3 , 3} )} + {H}_{3 , 4} \cdot {\vert {A}_{{f}_{i n}} \vert}^{3} \cdot {e}^{( 3 \cdot {ϕ}_{{f}_{in}} + {ϕ}_{3 , 4} )} \qquad ( 4 )$$

In above formula (4),

$${H}_{3 , 4} \cdot {\vert {A}_{{f}_{in}} \vert}^{3} \cdot {e}^{( 3 \cdot {ϕ}_{{f}_{in}} + {ϕ}_{3 , 4} )}$$

is a DTF-independent term.

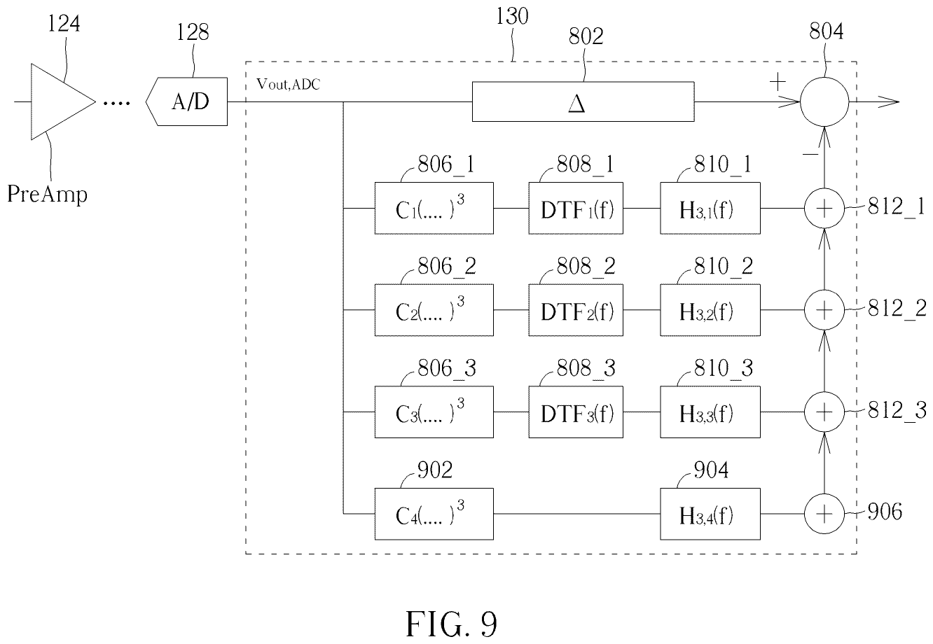

FIG. 9 is a diagram illustrating another implementation of the NLC circuit 130 according to an embodiment of the present invention. In this embodiment, the NLC circuit 130 may calculate an HD3 estimate according to the aforementioned formula (4). The difference between circuit designs shown in FIG. 8 and FIG. 9 is that the compensator of the NLC circuit 130 in FIG. 9 further includes a plurality of processing circuits 902, 904 and a combining circuit (which acts as an adder) 906. The processing circuit 902 calculates the cube of an ADC output V_{out,ADC}. The processing circuit 904 is a digital filter that operates on a NLC parameter set selected from an LUT that is created by production characterization. The HD3 estimate is generated from summing up outputs of the processing circuits 810_1-810_3 and 906. The combining circuit 804 acts as a subtractor for subtracting the HD3 estimate from a delayed version of the ADC output V_{out,ADC} for HD3 cancelation. The implementation shown in FIG. 9 is for illustrative purposes only, and is not meant to be a limitation of the present invention. In practice, any means capable of performing non-linearity compensation based at least partly on DFT measurement result(s) that are source impedance dependent falls within the scope of the present invention.

In some embodiments of the present invention, the non-linearity compensation method may further use a temperature sensor for sensing temperature of on-chip components of the RX chain to generate a temperature sensing output. The non-linearity compensation performed at the NLC circuit 130 may be adjusted based on the temperature sensing output. For example, the filtering components' weights used by the compensator of the NLC circuit 130 shown in FIG. 8 or FIG. 9 may be adjusted based on temperature using a 1st order or higher order temperature coefficient.

Regarding the wideband receiver design shown in FIG. 1, the proposed non-linearity compensation method performs measurement to obtain at least one measurement result MR1/MR2/MR3 for at least one node N1/N2/N3 of the RX chain, and performs non-linearity compensation upon a processed signal (e.g., an ADC output) generated by the RX chain, where the at least one measurement result MR1/MR2/MR3 is source impedance dependent, and the non-linearity compensation at the NLC circuit 130 is based at least partly on the at least one measurement result MR1/MR2/MR3. Hence, the proposed non-linearity compensation method calculates an HD3 estimate and subtracts the HD3 estimate from a processed signal (e.g., ADC output) of the RX chain for non-linearity compensation. Alternatively, a wideband receiver design may adopt another HD3 cancellation technique proposed by the present invention to protect performance of an NLC circuit from being affected by source impedance variations.

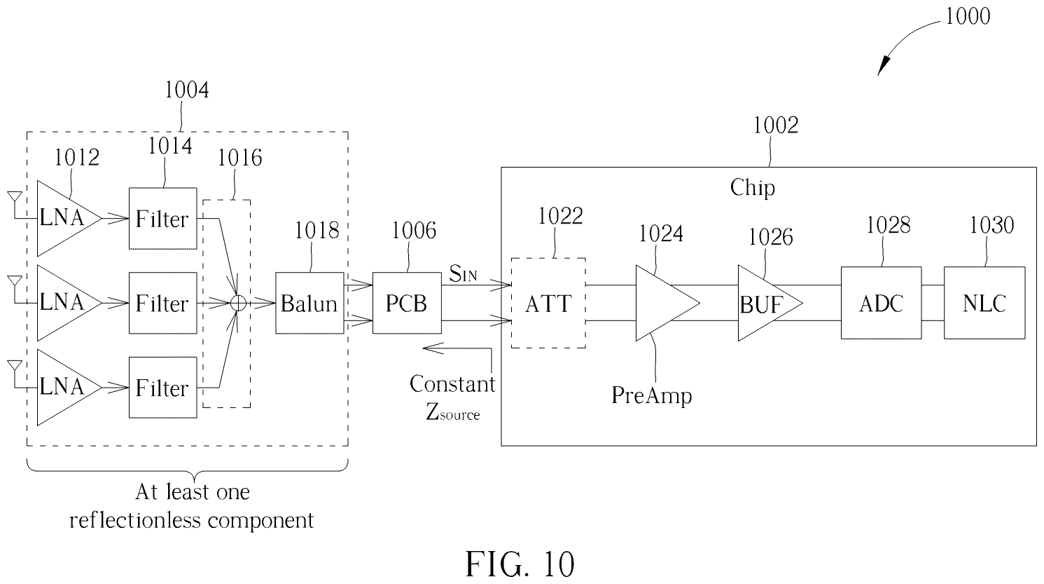

FIG. 10 is a diagram illustrating a wideband receiver that employs another proposed non-linearity compensation method according to an embodiment of the present invention. The wideband receiver 1000 includes a chip 1002 and an off-chip source 1004. The chip 1002 is mounted on a PCB 1006. The chip 1002 is coupled to the off-chip source 1004 via transmission lines routed on the PCB 1006, and receives an input signal S_{IN} provided from the off-chip source 1004. Specifically, the chip 1002 includes on-chip components of an RX chain for processing the input signal S_{IN}, and the off-chip source 1004 includes off-chip components of the RX chain for providing the input signal S_{IN}. The off-chip source 1004 includes a plurality of channels, each having an LNA 1012 and a filter 1014. For example, the filter 1014 may be a BPF. The off-chip source 1004 further includes an RF combiner 1016 and a balun 1018. The chip 1002 may include an attenuator circuit 1022, a pre-amplifier circuit 1024, a buffer circuit 1026, an ADC circuit 1028, and an NLC circuit 1030. For example, the attenuator circuit 1022 may be a DSA for applying a variable gain to a chip input (i.e., input signal S_{IN}). To address the source-dependent distortion issue, the present invention proposes a non-linearity compensation method that is capable of improving the HD3 cancellation performance. In this embodiment, the proposed non-linearity compensation method mitigates or cancels the source-dependent distortion by using off-chip reflectionless component(s) in the off-chip source 1004. That is, the proposed non-linearity compensation method may make the source impedance Z_{source} Viewed from the chip 1002 independent of the off-chip components. In this way, HD3 is not a function of the source impedance Z_{source}, and a broadband source impedance match can be achieved. Specifically, the source 1004 includes off-chip components of the RX chain for providing the input signal S_{IN}, and at least one of the off-chip components is an off-chip reflectionless component. For example, the off-chip reflectionless component may be the balun 1018, the RF combiner 1016, the filter 1014, or the LNA 1012. By way of example, but not limitation, all off-chip components (e.g., balun 1018, RF combiner 1016, filters 1014, and LNAs 1012) included in the off-chip source 1004 may be implemented using reflectionless components.

Since there is a constant source impedance Z_{source} at the chip input, any applicable digital non-linearity compensation scheme can be employed by the NLC circuit 1030. For example, the digital non-linearity compensation scheme employed by the NLC circuit 1030 may be based on a Weiner model, a Hammerstein model, a general polynomial (GNP) model, or a Volterra model.

In some embodiments of the present invention, the non-linearity compensation method may further use a temperature sensor for sensing temperature of on-chip components of the RX chain to generate a temperature sensing output. The non-linearity compensation performed at the NLC circuit 1030 may be adjusted based on the temperature sensing output. For example, the filtering components' weights used by NLC circuit 1030 are adjusted based on temperature using a 1st order or higher order temperature coefficient.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A non-linearity compensation method comprising:
performing measurement to obtain at least one measurement result for at least one first node of a receiver (RX) chain, wherein the at least one measurement result is source impedance dependent; and
performing non-linearity compensation upon a processed signal generated by the RX chain, wherein the non-linearity compensation is based at least partly on the at least one measurement result.

2. The non-linearity compensation method of claim 1, wherein performing measurement to obtain the at least one measurement result for the at least one first node of the RX chain comprises: measuring impedance at each of the at least one first node.

3. The non-linearity compensation method of claim 2, wherein the RX chain comprises on-chip components including an attenuator circuit, a pre-amplifier circuit, and a buffer circuit; the pre-amplifier circuit is coupled between the attenuator circuit and the buffer circuit; and the at least one first node comprises one or more of an input of the attenuator circuit, an input of the pre-amplifier circuit, and an output of the pre-amplifier circuit.

4. The non-linearity compensation method of claim 2, further comprising:
during production characterization, measuring impedance at the at least one first node under different frequency bands and different transmission line lengths, to generate a plurality of non-linearity compensation parameter sets for the different frequency bands, respectively;
wherein the non-linearity compensation is based at least partly on the at least one measurement result and a non-linearity compensation parameter set, where the non-linearity compensation parameter set is selected from the plurality of non-linearity compensation parameter sets.

5. The non-linearity compensation method of claim 1, wherein performing measurement to obtain the at least one measurement result for the at least one first node of the RX chain comprises:
measuring a distortion transfer function (DTF) between each of the at least one first node and a second node of the RX chain.

6. The non-linearity compensation method of claim 5, wherein the RX chain comprises on-chip components including an attenuator circuit, a pre-amplifier circuit, and a buffer circuit; the pre-amplifier circuit is coupled between the attenuator circuit and the buffer circuit; and the at least one first node comprises one or more of an input of the attenuator circuit, an input of the pre-amplifier circuit, and an output of the pre-amplifier circuit.

7. The non-linearity compensation method of claim 6, wherein the on-chip components further include an analog-to-digital converter (ADC) circuit; the buffer circuit is coupled between the pre-amplifier circuit and the ADC circuit; and the second node is an output of the ADC circuit or after digital processing of the output of the ADC circuit.

8. The non-linearity compensation method of claim 5, further comprising:
during production characterization, measuring DTF at the at least one first node under different frequency bands and different transmission line lengths, to generate a plurality of non-linearity compensation parameter sets for the different frequency bands, respectively;
wherein the non-linearity compensation is based at least partly on the at least one measurement result and a non-linearity compensation parameter set, where the non-linearity compensation parameter set is selected from the plurality of non-linearity compensation parameter sets.

9. The non-linearity compensation method of claim 5, wherein the non-linearity compensation is based at least partly on the at least one measurement result and a DTF-independent term.

10. The non-linearity compensation method of claim 1, further comprising:
sensing temperature of on-chip components of the RX chain to generate a temperature sensing output;
wherein the non-linearity compensation is adjusted based on the temperature sensing output.

11. A distortion transfer function (DTF) estimation method comprising:
providing a stimulus injected to a first node of a receiver (RX) chain;
performing measurement at a second node of the RX chain to generate a measurement result; and
estimating a DTF between the first node and the second node according to the stimulus and the measurement result.

12. The DTF estimation method of claim 11, wherein the RX chain comprises on-chip components including an attenuator circuit, a pre-amplifier circuit, and a buffer circuit; the pre-amplifier circuit is coupled between the attenuator circuit and the buffer circuit; and the first node is an input of the attenuator circuit, an input of the pre-amplifier circuit, or an output of the pre-amplifier circuit.

13. The DTF estimation method of claim 12, wherein the on-chip components further include an analog-to-digital converter (ADC) circuit; the buffer circuit is coupled between the pre-amplifier circuit and the ADC circuit; and the second node is an output of the ADC circuit or after digital processing of the output of the ADC circuit.

14. The DTF estimation method of claim 11, wherein providing the stimulus injected to the first node of the RX chain comprises:
generating the stimulus by using a digital-to-analog converter (DAC) circuit, a phase-clocked loop (PLL) circuit, an oscillator circuit, or a 1-bit digital waveform.

15. The DTF estimation method of claim 14, wherein the stimulus is generated by using the DAC circuit, and the DAC circuit is a current DAC, a resistive DAC, or a capacitive DAC.

16. The DTF estimation method of claim 15, wherein the DAC circuit employs a noise shaping technique.

17. The DTF estimation method of claim 15, wherein the RX chain comprises on-chip components including an analog-to-digital converter (ADC) circuit, and the DAC circuit is clocked at a rate higher than a sampling rate of the ADC circuit.

18. A non-linearity compensation method comprising:
receiving, by a chip, an input signal from a source, wherein the chip comprises on-chip components of a receiver (RX) chain for processing the input signal, the source comprises off-chip components of the RX chain for providing the input signal, and at least one of the off-chip components is an off-chip reflectionless component; and
performing non-linearity compensation upon a processed signal generated by the RX chain.

19. The non-linearity compensation method of claim 18, wherein the off-chip reflectionless component is a balun, a radio-frequency (RF) combiner, a filter, or a low-noise amplifier (LNA).

20. The non-linearity compensation method of claim 18, further comprising:
sensing temperature of the on-chip components of the RX chain to generate a temperature sensing output;
wherein the non-linearity compensation is adjusted based on the temperature sensing output.
